(19) United States
(12) Patent Application Publication
(10) Pub. No.: US 2025/0379112 A1
(43) Pub. Date: Dec. 11, 2025

(54) SEMICONDUCTOR DEVICE INCLUDING A THERMAL RELIEF LAYER

(71) Applicant: Sandisk Technologies, Inc., Milpitas, CA (US)

(72) Inventors: Wei Hong Tew, Penang (MY); Tze Ping Chan, Penang (MY); Chun Sean Lau, Penang (MY)

(73) Assignee: Sandisk Technologies, Inc., Milpitas, CA (US)

(21) Appl. No.: 18/737,427

(22) Filed: Jun. 7, 2024

(51) Int. Cl. H01L 23/367; H01L 23/00; H01L 23/31; H01L 23/373; H01L 25/065

(52) U.S. Cl. CPC H01L 23/3672; H01L 23/3121; H01L 23/3736; H01L 24/48; H01L 25/0652; H01L 25/0657; H01L 2224/48145; H01L 2224/48227; H01L 2225/06506; H01L 2225/0651; H01L 2225/06548; H01L 2225/06562; H01L 2225/06575; H01L 2225/06589; H01L 2924/1438

(57) ABSTRACT

A semiconductor device includes a stack of semiconductor dies mounted on a substrate. The stack may be offset to allow wire bonding of the dies to each other and the substrate. The stack may further include a thermal relief layer mounted between semiconductor dies at or near the middle of the stack to withdraw heat from semiconductor dies at and/or near the middle of in the stack.

### BACKGROUND

The strong growth in demand for portable consumer electronics is driving the need for high-capacity storage devices. Non-volatile semiconductor memory devices are widely used to meet the ever-growing demands on digital information storage and exchange. Their portability, versatility and rugged design, along with their high reliability and large capacity, have made such memory devices ideal for use in a wide variety of electronic products, including for example digital cameras, digital music players, video game consoles, computers, cellular telephones and SSD (solid state drives).

While many varied packaging configurations are known, flash memory semiconductor packages may in general be assembled as system-in-a-package (SIP), where a controller die and a number of memory dies are mounted and interconnected to an upper surface of substrate such as a printed circuit board. Typically, a number of memory dies are stacked on top of each other, for example in a stepped, offset configuration. Electrical connections are formed between the dies and the substrate and the package may then be encapsulated in mold compound. In a so-called BGA (ball grid array package), solder balls may be mounted on a bottom surface of the SiP memory package for electrically and physically coupling the SiP memory to the printed circuit board.

Current generation SiP memory packages are formed using 3D NAND, such as 3D BiCS (Bit Cost Scaling) and V-NAND. As the thicknesses of these memory dies decrease, the number of such dies which may be stacked and used in a package is increasing. However, as the number of dies increases, heat conduction is becoming a bigger problem. Semiconductor memory dies at the bottom of the stack are able to conduct heat away through the substrate. Semiconductor memory dies at the top of the stack are able to conduct heat away through the mold compound, and/or a thermal interface member (TIM) mounted on top of the semiconductor package. The semiconductor memory dies which are least able to dissipate heat are the dies in the middle of the die stack.

### DESCRIPTION OF THE DRAWINGS

FIG. 1 is a flowchart of the overall fabrication process of semiconductor device according to embodiments of the present invention.

FIG. 2 is a top view of a substrate used in the assembly of a semiconductor device according to an embodiment of the present technology.

FIG. 3 is a side cross-sectional view of a substrate used in the assembly of a semiconductor device according to an embodiment of the present technology.

FIG. 4 is a side cross-sectional view of a semiconductor device at a first step in the assembly process according to an embodiment of the present technology.

FIG. 5 is a perspective view of a semiconductor device at a first step in the assembly process according to an embodiment of the present technology.

FIG. 6 is a side cross-sectional view of a semiconductor device at a second step in the assembly process according to an embodiment of the present technology.

FIG. 7 is a perspective view of a semiconductor device at a second step in the assembly process according to an embodiment of the present technology.

FIG. 8 is a side cross-sectional view of a semiconductor device at a third step in the assembly process according to an embodiment of the present technology.

FIG. 9 is an end cross-sectional view of a semiconductor device at a third step in the assembly process according to an embodiment of the present technology.

FIG. 10 is a perspective view of a semiconductor device at a third step in the assembly process according to an embodiment of the present technology.

FIG. 11 is a side cross-sectional view of a semiconductor device at a fourth step in the assembly process according to an embodiment of the present technology.

FIG. 12 is an end cross-sectional view of a semiconductor device at a fourth step in the assembly process according to an embodiment of the present technology.

FIG. 13 is a perspective view of a semiconductor device at a fourth step in the assembly process according to an embodiment of the present technology.

FIG. 14 is a side cross-sectional view of a semiconductor device at a fifth step in the assembly process according to an embodiment of the present technology.

FIG. 15 is an end cross-sectional view of a semiconductor device at a fifth step in the assembly process according to an embodiment of the present technology.

FIG. 16 is a perspective view of a semiconductor device at a fifth step in the assembly process according to an embodiment of the present technology.

FIG. 17 is a side cross-sectional view of a semiconductor device at a sixth step in the assembly process according to an embodiment of the present technology.

FIG. 18 is a side cross-sectional view of a completed semiconductor device according to an embodiment of the present technology.

FIG. 19 is an end cross-sectional view of a completed semiconductor device showing heat conduction away from the device according to an embodiment of the present technology.

FIG. 20 is an end cross-sectional view of a completed semiconductor device showing heat conduction away from the device according to an alternative embodiment of the present technology.

FIG. 21 is an end cross-sectional view of a completed semiconductor device showing heat conduction away from the device according to a further alternative embodiment of the present technology.

FIG. 22 is an end cross-sectional view of a completed semiconductor device showing heat conduction away from the device according to another alternative embodiment of the present technology.

FIGS. 23-25 are side cross-sectional, perspective and end cross-sectional views of a semiconductor device according to an alternative embodiment of the present technology including through silicon vias.

FIG. 26 is a heat distribution map of a conventional semiconductor device.

FIG. 27 is a heat distribution map of a semiconductor device according to the present technology including a thermal relief layer.

### DETAILED DESCRIPTION

The present technology will now be described with reference to the drawings, which in embodiments, relate to a semiconductor device having a stack of semiconductor dies mounted on a substrate. The stack may be offset to allow wire bonding of the dies to each other and the substrate. The stack may further include a thermal relief layer mounted between semiconductor dies at or near the middle of the stack to withdraw heat from semiconductor dies at and/or near the middle of in the stack. In embodiments, the thermal relief layer may be mounted to the substrate to conduct heat away from the die stack through the substrate. In further embodiments, the thermal relief layer may be a closed loop having an upper planar section on top of the die stack. In such embodiments, a thermal interface material (TIM) and heat sink may be provided above the die stack so that the thermal relief layer conducts heat away from the stack through the TIM and heat sink. Other configurations of the thermal relief layer are contemplated.

It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

The terms “top” and “bottom,” “upper” and “lower” and “vertical” and “horizontal,” and forms thereof, as may be used herein are by way of example and illustrative purposes only, and are not meant to limit the description of the technology inasmuch as the referenced item can be exchanged in position and orientation. Also, as used herein, the terms “substantially” and/or “about” mean that the specified dimension or parameter may be varied within an acceptable manufacturing tolerance for a given application. In one embodiment, the acceptable manufacturing tolerance is +0.15 mm, or alternatively, +2.5% of a given dimension.

For purposes of this disclosure, a physical or electrical connection may be a direct connection or an indirect connection (e.g., via one or more other parts). In some cases, when a first element is referred to as being connected, affixed, mounted or coupled to a second element (either physically or electrically), the first and second elements may be directly connected, affixed, mounted or coupled to each other or indirectly connected, affixed, mounted or coupled to each other (either physically or electrically). When a first element is referred to as being directly connected, affixed, mounted or coupled to a second element, then there are no intervening elements between the first and second elements (other than possibly an adhesive or melted metal used to connect, affix, mount or couple the first and second elements).

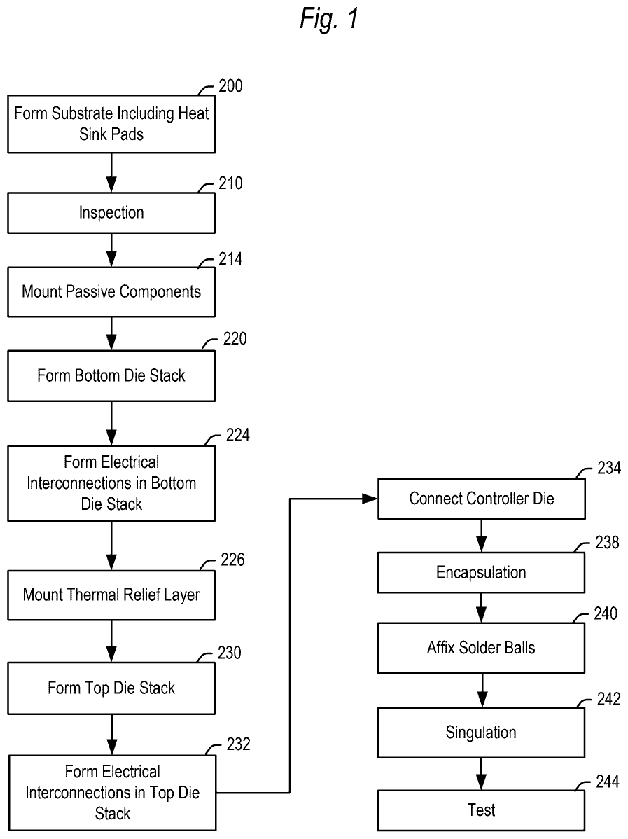

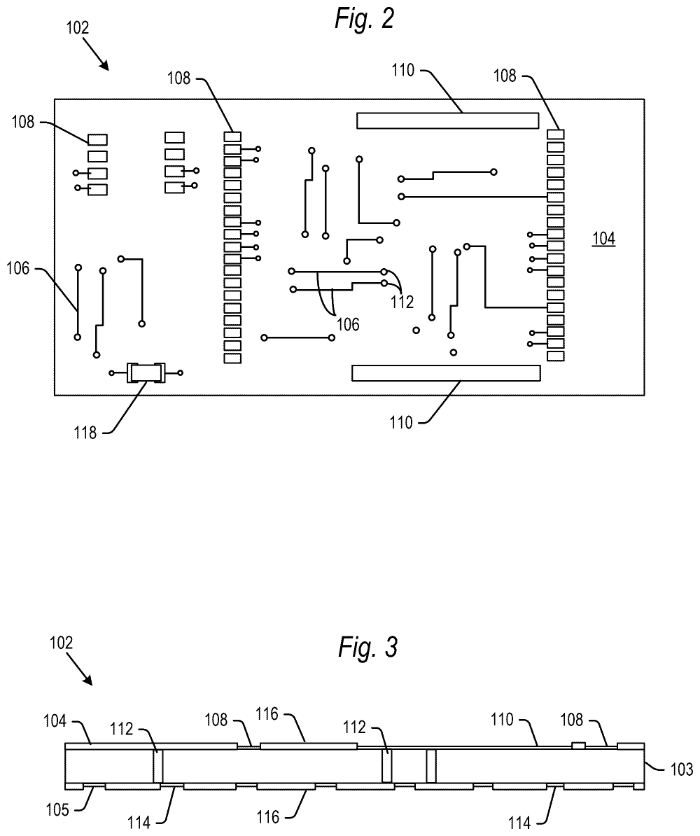

An embodiment of the present invention will now be explained with reference to the flowchart of FIG. 1 and the views of FIGS. 2 through 25. Although FIGS. 2 through 25 each show an individual semiconductor device 100, or a portion thereof, it is understood that the device 100 may be batch processed along with a plurality of other devices 100 on a substrate panel to achieve economies of scale. The number of rows and columns of semiconductor devices 100 on the substrate panel may vary.

The substrate 102 may be formed in step 200 as shown in the top and edge views of FIGS. 2 and 3, respectively. The substrate panel begins with a plurality of substrates 102 (again, one such substrate is shown in FIGS. 2 and 3). The substrate 102 may be a variety of different chip carrier mediums for transmitting signals between semiconductor dies on the substrate and a host device. Such chip carrier mediums may include a printed circuit board (PCB), a leadframe or a tape automated bonded (TAB) tape. Where substrate 102 is a PCB, the substrate may be formed of a core 103 having a top conductive layer 104 and a bottom conductive layer 105 as indicated in FIGS. 2 and 3. It is understood that the substrate may have more conductive layers, each separated by a dielectric core layer. The core 103 may be formed of various dielectric materials such as for example, polyimide laminates, epoxy resins including FR4 and FR5, bismaleimide triazine (BT), and the like. The conductive layers 104, 105 may be formed of copper or copper alloys, plated copper or plated copper alloys, Alloy 42 (42Fe/58Ni), copper plated steel, or other metals and materials known for use on substrate panels.

Conductance patterns are formed in one or both of the top and bottom conductive layers 104, 105. The conductance pattern(s) may include electrical traces 106 and contact pads 108 as shown for example in FIGS. 2 and 3. The traces 106 and contact pads 108 (only some of which are numbered in the figures) are by way of example, and the substrate 102 may include more traces and/or contact pads than is shown in the figures, and they may be in different locations than is shown in the figures. In accordance with one embodiment of the present technology, the top conductive layer 104 may further be etched to include a pair of heat sink pads 110, the purpose of which is explained below. The substrate 102 may be drilled to define a number of through-hole vias 112 in the substrate 102. The vias 112 (only some of which are numbered in the figures) are by way of example, and the substrate 102 may include more vias 112 than are shown in the figures, and they may be in different locations than are shown in the figures.

In embodiments, the finished semiconductor device 100 assembly may be used as a BGA (ball grid array) package. The lower conductance pattern 105 of the substrate 102 may be etched to include contact pads 114 for receiving solder balls as explained below. In further embodiments, the finished semiconductor device 100 may be an LGA (land grid array) package including contact fingers for removably coupling the finished device 100 within a host device. In such embodiments, the lower surface may include contact fingers instead of the contact pads that receive solder balls. The conductance pattern on the top and/or bottom surfaces of the substrate 102 may be formed by a variety of known processes, including for example various photolithographic processes. A solder mask 116 may be applied over the conductance patterns in the top and bottom surfaces, leaving the various contact pads 108, 114 exposed, and leaving the heat sink pads 110 exposed.

The substrate 102 may then be inspected and tested in step 210 to check electrical operation, and for contamination, scratches and discoloration. Assuming the substrate 102 passes inspection, passive components 118 (FIG. 2) may next be affixed to the substrate in a step 214. The one or more passive components may include for example one or more capacitors, resistors and/or inductors, though other components are contemplated. The passive component 118 shown is by way of example only, and the number, type and position may vary in further embodiments.

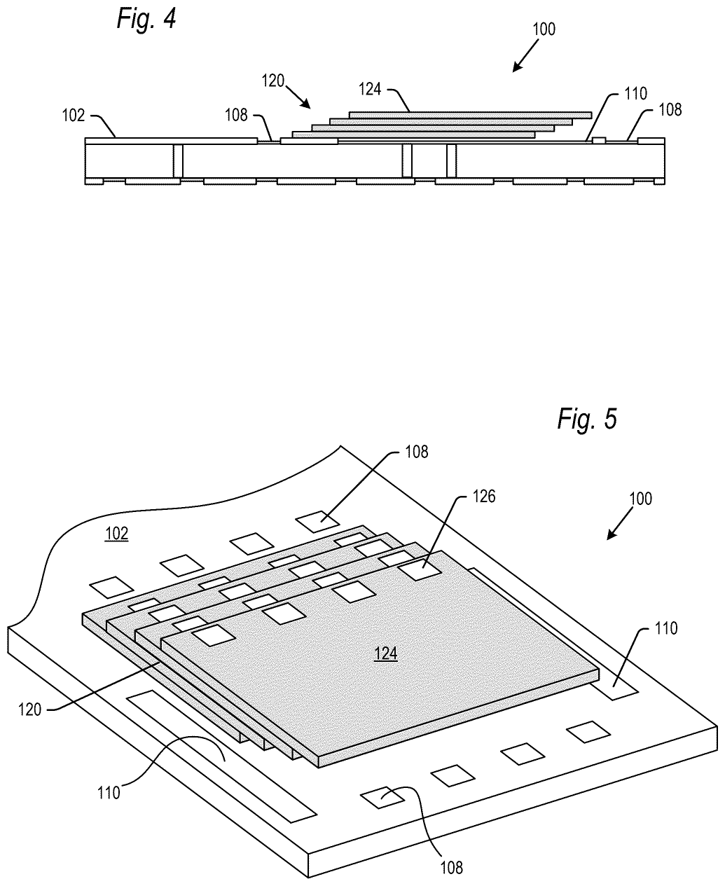

A die stack may next be formed on the substrate 102. In accordance with the present technology, the die stack may be grouped into a bottom portion and a top portion, separated by a thermal relief layer as explained below. The bottom die stack 120 may be mounted to the substrate 102 in step 220 and as shown in the side and perspective views of FIGS. 4 and 5, respectively. The dies 124 in the bottom die stack 120 may be mounted in a stepped, offset configuration to leave the bond pads 126 of each die 124 exposed as best seen in FIG. 5. As shown, each semiconductor die 124 may include a row of die bond pads 126 along an edge of the die 124. The number and positions of the bond pads 126 are for illustrative purposes only, and there may be many more bond pads in further embodiments. The dies 124 may be affixed to the substrate and/or each other using a die attach film. As one example, the die attach adhesive may be 8988UV epoxy from Henkel AG & Co. KGaA, cured to a B-stage to preliminarily affix the dies 124 in the stack 120, and subsequently cured to a final C-stage to permanently affix the dies 124 in the stack 120 upon completion of the semiconductor device 100.

The semiconductor dies 124 may for example be memory die such a NAND flash memory die, but other types of dies 124 may be used. The figures show an embodiment where there are four dies 124 in the bottom die stack 120. However, there may be more or less than four dies 124 in the bottom stack 120 in further embodiments.

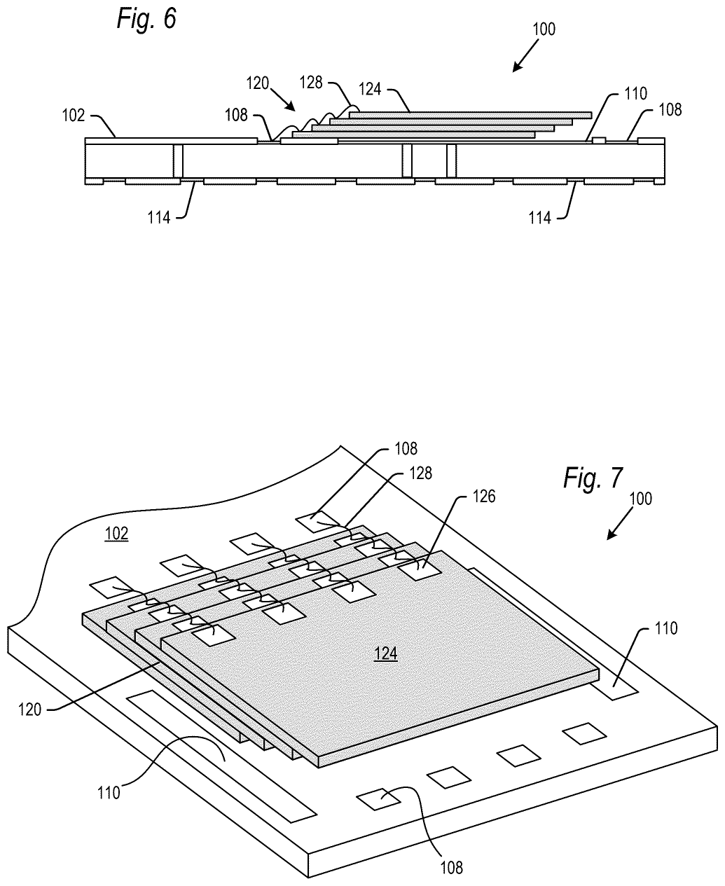

Referring now to side and perspective views of FIGS. 6 and 7 once the bottom die stack 120 is formed, the respective dies 124 in the stack 120 may be electrically connected to each other and the substrate in step 224 using bond wires 128 connected between each of the bond pads 126 of each die 124 in the stack. Each die bond pad 126 in the row of a semiconductor die may be electrically connected to the corresponding die bond pad 126 in the row of the next adjacent semiconductor die using a bond wire 128. Although bond wires 128 may be formed by a variety of technologies, in one embodiment, the bond wires 128 may be formed as reverse ball bond wire bonds using a wire bonding capillary in a known process.

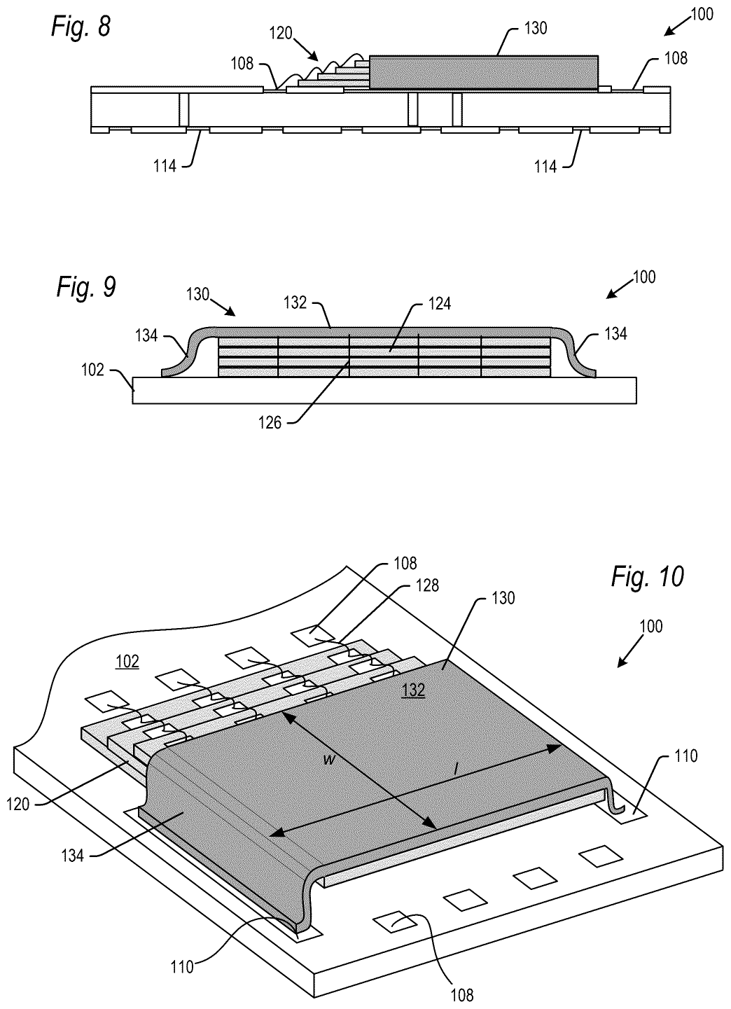

In accordance with aspects of the present technology, a thermal relief layer 130 may next be mounted on the bottom die stack 120 in step 226 as shown in the front view, the end view and the perspective view of FIGS. 8-10, respectively. The thermal relief layer 130 may be formed of a thermally conductive material such as for example copper. However, other materials and alloys may be used, including for example Aluminum, Copper Alloys such as copper-tungsten (Cu—W) or copper-molybdenum (Cu—Mo), Aluminum Alloys such as aluminum-silicon (Al—Si), alloys of Copper and Aluminum and graphite. In embodiments, the thermal relief layer may have a thickness ranging between 50 μm and 50 mm. The thermal relief layer may have thicknesses outside of this range in further embodiments.

As seen in FIGS. 8-10, the thermal relief layer 130 includes a main body section 132 and downwardly extending sides 134. As indicated in FIG. 10, the main body section 132 includes a length, l, slightly greater than a length of semiconductor dies 124, and a width, w, slightly less than a width of a semiconductor die 124 (so as not to interfere with the bond wires 128 on bond pads 126). The main body section 132 may have a length and/or with that is wider or narrower than this in further embodiments. Sides 134 may be provided with a length so that the main body section 132 may rest against the uppermost semiconductor die 124, and the sides 134 may extend downward from there into contact with heat sink pads 110. Bottom portions of the sides 134 may be affixed to heat sink pads 110 on both sides of the die stack 120, by a re-flowable metal such as solder, or a thermally conductive adhesive. Alternatively or additionally, the main body section 132 may be affixed to the uppermost semiconductor die 124 in stack 120, for example with a thermally conductive adhesive, and the sides 134 may simply the biased against heat sink pads 110.

As noted in the Background section, conduction of heat away from semiconductor dies in the stack is poorest toward the middle of the stack. Accordingly, the thermal relief layer 130 is provided so that the body section 132 draws heat away from this location, down through the sides 134 and into heat sink pads 110 where the heat may be dissipated through the substrate 102.

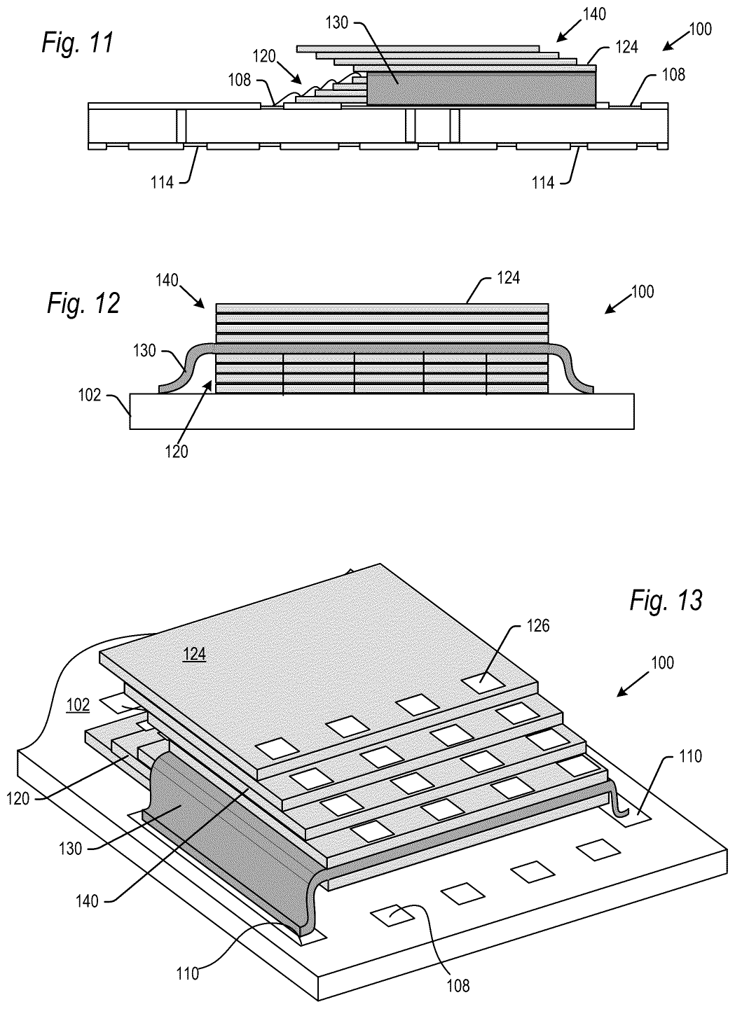

Referring now to the side view, the front view and the perspective view of FIGS. 11-13, respectively, a second die stack 140 of semiconductor dies 124 may next be affixed on top of the thermal relief layer 130 and first die stack 120 in step 230. The dies 124 in top stack 140 may be the same number and type of dies in the lower stack 120. However, in embodiments, the dies 124 in the top stack 140 may be offset, stepped in the opposite direction than the dies 124 in the bottom stack 120. While this minimizes the overall footprint of stacks 120 and 140 together, the dies in stacks 120 and 140 may be offset, stepped in the same direction in further embodiments. The lowermost die 124 in the top stack 140 may be bonded to an upper surface of the main body section 132 of the thermal relief layer 130, as for example by the DAF layer on a bottom surface of the bottommost die 124. In embodiments, the DAF used may be thermally conductive.

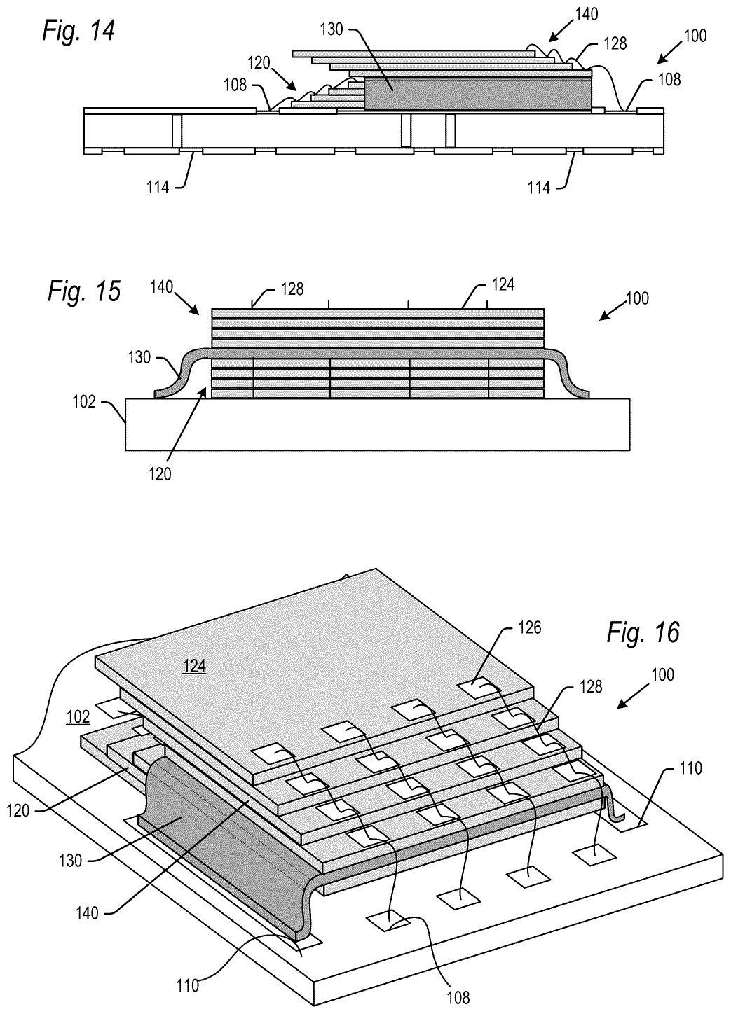

Referring now to the side cross-sectional view, the front cross-sectional view and perspective view of FIGS. 14-16, respectively, once the top die stack 140 is formed, the respective dies 124 in the stack 140 may be electrically connected to each other and the substrate 102 in step 232 using bond wires 128 connected between each of the bond pads 126 of each die 124 in the stack. Each die bond pad 126 in the row of a semiconductor die 124 may be electrically connected to the corresponding die bond pad 126 in the row of the next adjacent semiconductor die using a bond wire 128. Although bond wires 128 may be formed by a variety of technologies, in one embodiment, the bond wires 128 may be formed as reverse ball bond wire bond using a wire bonding capillary in a known process.

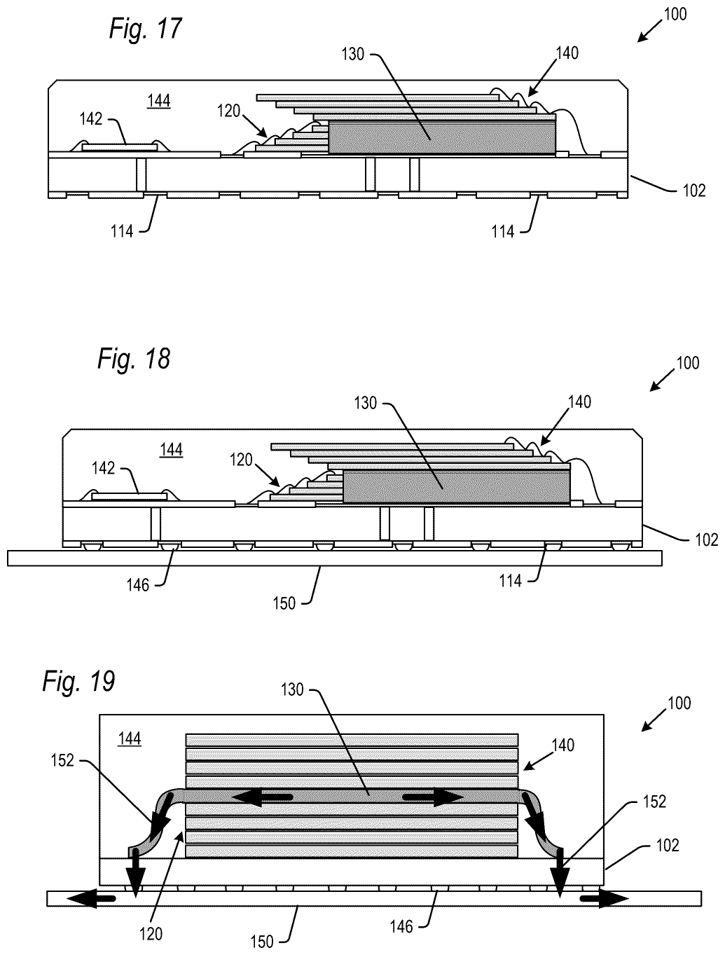

In step 234, a controller die 142 may be physically and electrically coupled to the substrate 102, as shown in the cross-sectional side view of FIG. 17. The controller die 142 may for example be an ASIC for controlling read/write operations to the semiconductor dies 124. Other types of controllers may be used, including specialized controllers such as graphics processing controllers and AI controllers. The controller 142 is shown wire bonded to the substrate 102 in FIG. 17, but the controller may be flip-chip bonded in further embodiments.

Following mounting and electrical connection of the die stacks and controller die, the die stacks, bond wires and at least a portion of the substrate may be encapsulated in a mold compound 144 in step 238 and as shown in FIG. 17. Mold compound 144 may include for example solid epoxy resin, Phenol resin, fused silica, crystalline silica, carbon black and/or metal hydroxide. Such mold compounds are available for example from Sumitomo Corp. and Nitto-Denko Corp., both having headquarters in Japan. Other mold compounds from other manufacturers are contemplated. The mold compound may be applied according to various known processes, including by transfer molding or injection molding techniques. The encapsulation process may be performed by FFT (Flow Free Thin) compression molding in further embodiments.

As shown in the cross-sectional side view of FIG. 18, after the die on the panel are encapsulated in step 238, solder balls 146 may be attached to the contact pads 114 on a bottom surface of the substrate 102. Solder balls 146 may be affixed to the substrate at an earlier stage of the package assembly in further embodiments.

The respective packages may be singulated in step 242 from the panel to form the finished semiconductor device 100 shown in FIG. 18. Each semiconductor device 100 may be singulated by any of a variety of cutting methods including sawing, water jet cutting, laser cutting, water guided laser cutting, dry media cutting, and diamond coating wire cutting. While straight line cuts will define generally rectangular or square shaped semiconductor device 100, it is understood that semiconductor device 100 may have shapes other than rectangular and square in further embodiments of the present invention.

Once cut into individual semiconductor devices 100, the devices may be tested in a step 244 to ensure the devices are functioning properly. As is known in the art, such testing may include electrical testing, burn in and other tests. The finished semiconductor devices 100 may be mounted on a host device such as printed circuit board (PCB) 150 shown in FIG. 18. The solder balls 146 may be positioned on a like pattern of contact pads on the PCB 150 are reflowed to physically and electrically couple the semiconductor device 100 to the PCB 150.

FIG. 19 is a cross-sectional end view of semiconductor device 100 showing operation of the thermal relief layer 130 to conduct heat away from the middle semiconductor dies in the stacks 120, 140. As indicated by the heat conduction arrows 152, heat may be conducted from the dies adjacent the upper and lower surfaces of the thermal relief layer 130, out to the sides of the thermal relief layer, down into the substrate 102 and then dissipated through the PCB 150.

In embodiments described above, there are equal numbers of semiconductor dies 124 above and below the thermal relief layer 130. However, it is understood that but there may be more or less semiconductor dies 124 above the thermal relief layer 130 than are below the thermal relief layer 130 in further embodiments. Moreover, the above describes two separate die stacks: a die stack 120 below the thermal relief layer 130 and a die stack 140 above the thermal relief layer. However, it is understood that the present technology may be treated is having a single die stack, for example comprised of die stacks 120 and 140, where the thermal relief layer is provided between two adjacent semiconductor dies 124 in the die stack. As noted above, such a die stack may have some dies extending in a first offset stepped direction, and some dies extending in a second, opposite offset stepped direction. Alternatively, all dies in the die stack may extend in a single offset stepped direction.

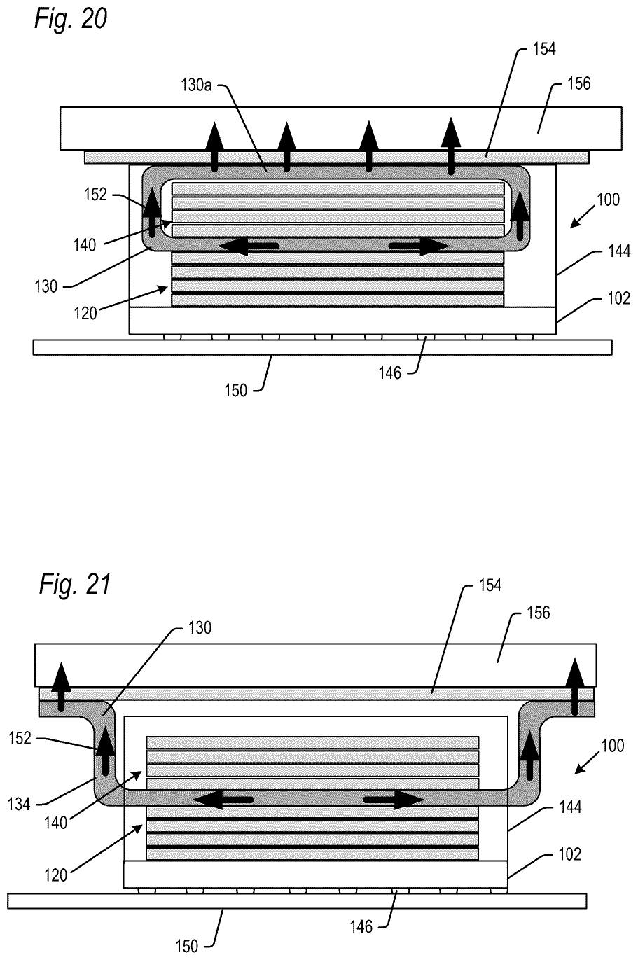

FIGS. 20-22 are cross-sectional end views of alternative configurations thermal relief layer 130. In FIG. 20, instead of extending downward, the thermal relief layer has side portions which extends upward, and then portion 130a extends across the major planar surfaces of the dies 124 in the upper stack 140 to form a closed loop around the upper stack 140. In this embodiment, the portion 130a may be positioned against mold chase during the encapsulation step 238, so that the portion 130a is exposed through the mold compound 144 at a top of semiconductor device 100. This embodiment may further include a thermal interface layer (TIM) 154 for conducting heat away from the portion 130a of the thermal relief layer 130. The TIM 154 may in turn be positioned against a heat sink or enclosure 156. In this embodiment, as indicated by the heat conduction arrows 152, heat may be conducted from the dies adjacent the upper and lower surfaces of the thermal relief layer 130, out to the sides of the thermal relief layer, up into portion 130a, where the heat is dissipated through the TIM 154 and heat sink/enclosure 156.

In the embodiment of FIGS. 19 and 20, the thermal relief layer 130 may be completely encased within the mold compound 144 (with the possible exception of a surface of portion 130a which may be exposed through the mold compound as described above). In the embodiment of FIG. 21, the side portions 134 of thermal relief layer 130 may extend outside of mold compound 144. In particular, during the encapsulation step 238 the thermal relief layer 130 may be positioned between the top and bottom mold plates so as to extend outside of the encapsulation enclosure. After the encapsulation step 238 is complete and after the semiconductor device 100 is mounted to the host device 150 and heat sink/enclosure 156, the side portions 134 of the thermal relief layer 130 may be bent upward into contact with TIM 154. Thereafter, heat may be conducted away from the middle semiconductor dies in the stacks 120, 140 along arrows 152 into the TIM 154 and heat sink/enclosure 156.

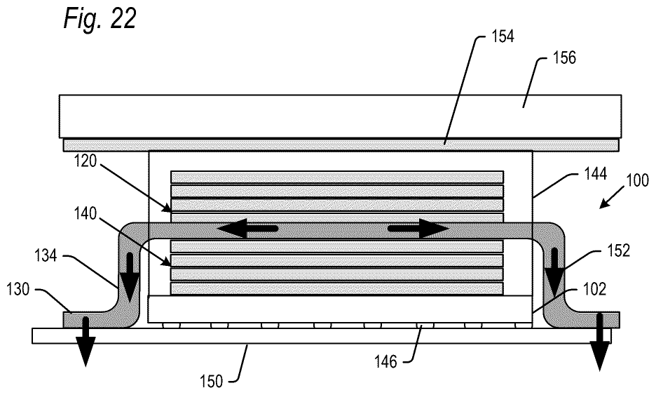

The embodiment of FIG. 22 may be identical to the embodiment of FIG. 21, however, instead of the side portions 134 bending upward outside of the mold compound 144 into contact with TIM 154, the side portions 134 may bend downward to thermally couple the thermal relief layer 130 with the host device 150. Heat may be conducted away from the middle semiconductor dies in die stacks 120, 140 along arrows 152 through the side portions 134 and down into the PCB 150. The TIM 154 and heat sink/enclosure 156 are not used by the thermal relief layer 130 in this embodiment to conduct heat from the semiconductor die stacks 120, 140, but may optionally be included any way to conduct heat away from the semiconductor device 100.

In embodiments described above, the die stacks 120, 140 may have a single thermal relief layer 130 for conducting heat away from the middle dies in the stacks. In a further embodiment, there may be more than one thermal relief layer 130 in the stacks 120, 140. These multiple thermal relief layers 130 may have main body portions positioned between selected dies in the die stack(s). Such an embodiment may for example include to such thermal relief layers 130, one having side portions extending upward, as shown for example in FIG. 21, and the second having side portions extending downward, as shown for example in FIG. 22.

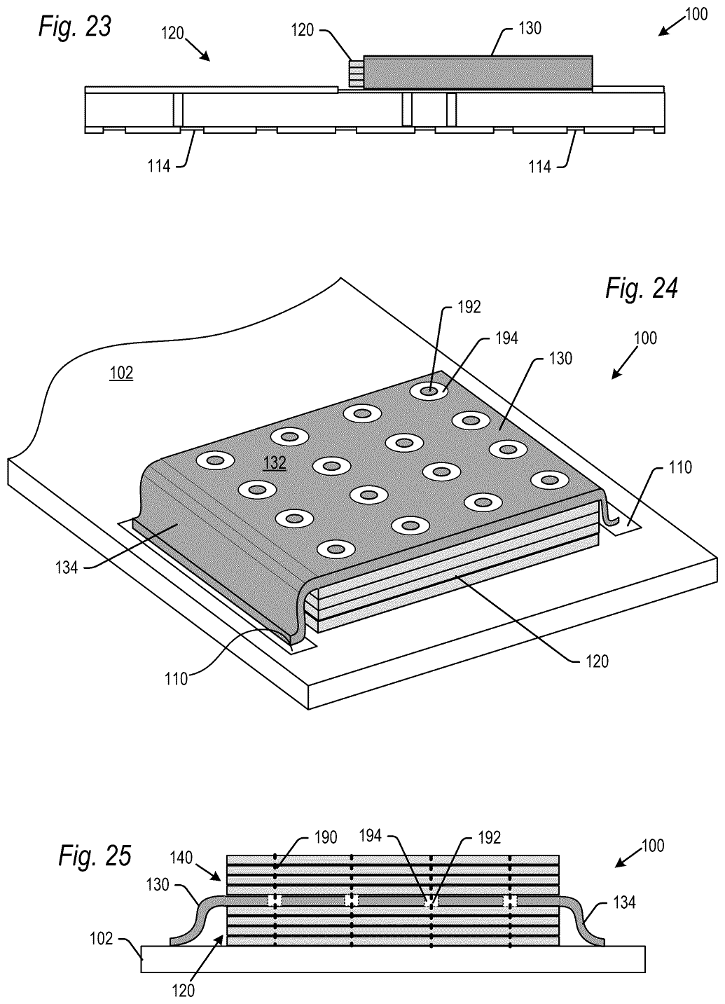

In embodiments described above, the dies 124 are provided in an offset, stepped configuration to allow access to the die bond pads 126 for electrically coupling the semiconductor dies to each other and the substrate 102 using bond wires 128. In a further embodiment of the present technology, the semiconductor dies 124 may be stacked without an offset. Such an embodiment is shown in the cross-sectional side, perspective and cross-sectional end views of FIGS. 23-25 respectively. In such an embodiment, the semiconductor dies may be electrically coupled to each other and substrate 102 using through silicon vias (TSVs) 190 (shown in dashed lines in FIG. 25) within the semiconductor dies 124 of die stacks 120, 140.

Such an embodiment may include a thermal relief layer 130 as described above. Where the thermal relief layer 130 is formed of copper or other likely conductive material, vias 192 may be formed through the main body portion 132 of the thermal relief layer 130, aligned with the TSVs 190 in the semiconductor dies 124 as seen in FIGS. 24 and 25. Such vias in the thermal relief layer may be surrounded by dielectric material 194 to maintain electrical separation of the TSVs through the thermal relief layer. Holes may be drilled or otherwise formed in the thermal relief layer and filled with dielectric material 194. Thereafter, vias 192 may be formed within the dielectric material 194 that align with the TSVs 190 in the bottom and top dies stacks 120, 140. The number and position of TSVs 190, vias 192 and dielectric materials 194 shown in the figures is by way of example only and may vary in further embodiments. Instead of including dielectric material around the vias 192, the thermal relief layer may alternatively be formed of a thermally conductive but electrically insulating material.

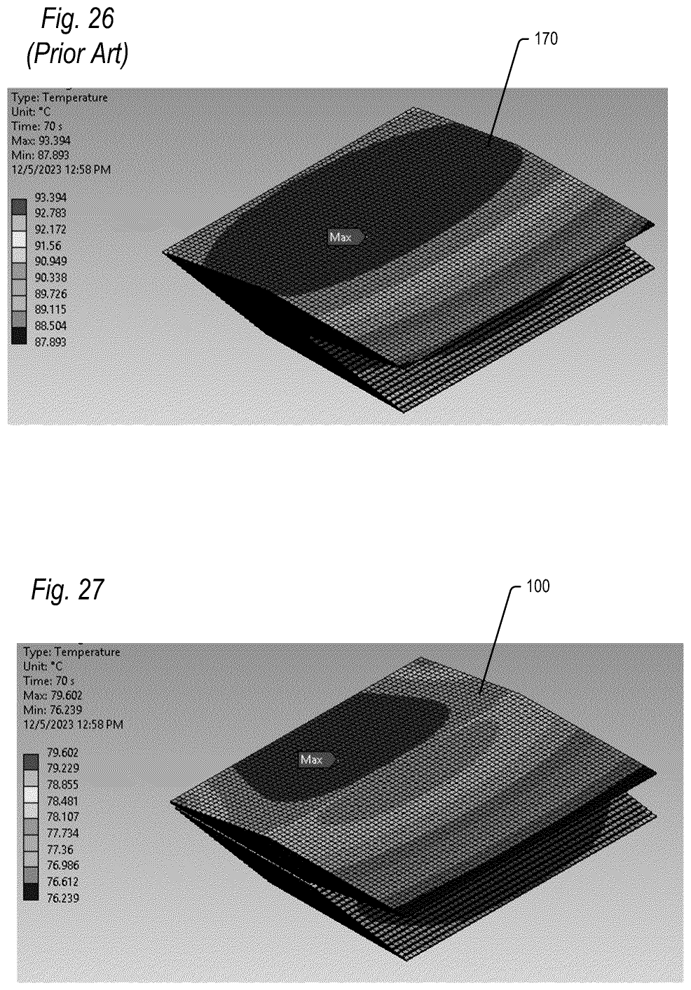

FIG. 26 illustrates a heat distribution map showing temperatures across semiconductor dies within a die stack of a conventional semiconductor device 170 not including a thermal relief layer. FIG. 27 illustrates a heat distribution map showing temperatures across semiconductor dies within a die stack of a semiconductor device 100 including a thermal relief layer 130 according to embodiments of the present technology. In actual tests, the maximum temperature in the dies of conventional semiconductor device 170 was about 93° C. By contrast, the maximum temperature of the dies in semiconductor device 100 including thermal relief layer 130 was about 80° C. Thus, it was shown that the thermal relief layer 130 was effective in removing heat from the middle of the semiconductor die stacks and reducing the overall temperature of the die stacks by around 13° C.

In summary, in one example, the present technology relates to a semiconductor device, comprising: a substrate; a plurality of semiconductor dies stacked on each other on the substrate, each semiconductor die of the plurality of semiconductor dies having first and second opposed planar surfaces; and a thermal relief layer provided between the first planar surface of a first semiconductor die of the plurality of semiconductor dies and the second planar surface of a second semiconductor die of the plurality of semiconductor dies, the thermal relief layer conducting heat away from at least the first and second semiconductor dies and out of the semiconductor device.

In another example, the present technology relates to a semiconductor device, comprising: a substrate; a first plurality of semiconductor dies stacked on each other on the substrate, each semiconductor die of the first plurality of semiconductor dies having a first group of bond pads at an edge of each semiconductor die of the first plurality of semiconductor dies; a first set of bond wires electrically coupled to the first group of bond pads and electrically coupling the first plurality of semiconductor dies to the substrate; a second plurality of semiconductor dies stacked on each other, each semiconductor die of the second plurality of semiconductor dies having a second group of bond pads at an edge of each semiconductor die of the second plurality of semiconductor dies; a second set of bond wires electrically coupled to the second group of bond pads and electrically coupling the second plurality of semiconductor dies to the substrate; and a thermal relief layer provided between first and second plurality of semiconductor dies, the thermal relief layer conducting heat away from semiconductor dies of the first and second plurality of semiconductor dies adjacent the thermal relief layer and out of the semiconductor device.

In a further example, the present technology relates to a semiconductor device, comprising: a substrate; a plurality of semiconductor dies stacked on each other on the substrate, each semiconductor die of the plurality of semiconductor dies having first and second opposed planar surfaces; and thermal relief means, provided between the first planar surface of a first semiconductor die of the plurality of semiconductor dies and the second planar surface of a second semiconductor die of the plurality of semiconductor dies, for conducting heat away from at least the first and second semiconductor dies and out of the semiconductor device.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A semiconductor device, comprising:
a substrate;
a plurality of semiconductor dies stacked on each other on the substrate, each semiconductor die of the plurality of semiconductor dies having first and second opposed planar surfaces; and
a thermal relief layer provided between the first planar surface of a first semiconductor die of the plurality of semiconductor dies and the second planar surface of a second semiconductor die of the plurality of semiconductor dies, the thermal relief layer conducting heat away from at least the first and second semiconductor dies and out of the semiconductor device.

2. The semiconductor device of claim 1, wherein the thermal relief layer comprises a main body section, and sides that extend from the main body section into contact with the substrate.

3. The semiconductor device of claim 2, wherein the substrate comprises heat sink pads configured to receive the sides of the thermal relief layer.

4. The semiconductor device of claim 1, further comprising a thermal interface material provided on the semiconductor device on a side of the plurality of semiconductor dies opposite the substrate.

5. The semiconductor device of claim 4, wherein the thermal relief layer comprises a main body section, and sides that extend from the main body section into contact with the thermal interface layer.

6. The semiconductor device of claim 1, wherein the thermal relief layer comprises a main body section having first and second surfaces, and wherein the second surface of the main body section is affixed to the first planar surface of a first semiconductor die with a thermally conductive adhesive.

7. The semiconductor device of claim 6, wherein the first semiconductor die includes a row of bond pads along an edge of the first semiconductor die, wherein the main body section is sized to affix to the first semiconductor die while leaving the row of bond pads exposed.

8. The semiconductor device of claim 1, wherein the thermal relief layer comprises a main body section having first and second surfaces, and wherein the second planar surface of the second semiconductor die is affixed to the first surface of the main body section with a thermally conductive die attach film on the second planar surface of a second semiconductor die.

9. The semiconductor device of claim 1, wherein the thermal relief layer is formed of one of copper and alloys thereon, and aluminum and alloys thereof.

10. The semiconductor device of claim 1, wherein there are a same number of semiconductor dies of the plurality of semiconductor dies below the thermal relief layer as there are semiconductor dies of the plurality of semiconductor dies above thermal relief layer.

11. The semiconductor device of claim 1, wherein the semiconductor dies below the thermal relief layer are offset stepped in a first direction, and the semiconductor dies above thermal relief layer are offset stepped in a second direction opposite the first direction.

12. The semiconductor device of claim 1, wherein the semiconductor dies below the thermal relief layer are offset stepped in a first direction, and the semiconductor dies above thermal relief layer are offset stepped in a second direction which is the same direction as the first direction.

13. The semiconductor device of claim 1, wherein the semiconductor dies above and below the thermal relief layer are stacked directly on top of each other, and wherein the semiconductor dies are electrically coupled to each other and the substrate using through silicon vias, the through silicon vias in the semiconductor dies above and below the thermal relief layer electrically coupled to each other through the thermal relief layer using electrically isolated vias formed through the thermal relief layer.

14. The semiconductor device of claim 1, further comprising mold compound for encapsulating the plurality of semiconductor dies, wherein the thermal relief layer comprises a main body section, and sides that extend from the main body section, the sides contained within the mold compound.

15. The semiconductor device of claim 1, further comprising mold compound for encapsulating the plurality of semiconductor dies, wherein the thermal relief layer comprises a main body section, and sides that extend from the main body section, the sides having first portions contained within the mold compound and second portions extending from the mold compound.

16. A semiconductor device, comprising:
a substrate;
a first plurality of semiconductor dies stacked on each other on the substrate, each semiconductor die of the first plurality of semiconductor dies having a first group of bond pads at an edge of each semiconductor die of the first plurality of semiconductor dies;
a first set of bond wires electrically coupled to the first group of bond pads and electrically coupling the first plurality of semiconductor dies to the substrate;
a second plurality of semiconductor dies stacked on each other, each semiconductor die of the second plurality of semiconductor dies having a second group of bond pads at an edge of each semiconductor die of the second plurality of semiconductor dies;
a second set of bond wires electrically coupled to the second group of bond pads and electrically coupling the second plurality of semiconductor dies to the substrate; and
a thermal relief layer provided between first and second plurality of semiconductor dies, the thermal relief layer conducting heat away from semiconductor dies of the first and second plurality of semiconductor dies adjacent the thermal relief layer and out of the semiconductor device.

17. The semiconductor device of claim 16, wherein the thermal relief layer comprises a main body section, and sides that extend from the main body section into contact with the substrate.

18. The semiconductor device of claim 17, wherein the substrate comprises heat sink pads configured to receive the sides of the thermal relief layer.

19. The semiconductor device of claim 17, wherein the bond wires extend off of a first edge of the first plurality of semiconductor dies, and the sides of the thermal relief layer extends over a second edge of the first plurality of semiconductor dies, the second edge being adjacent to the first edge.

20. A semiconductor device, comprising:
a substrate;
a plurality of semiconductor dies stacked on each other on the substrate, each semiconductor die of the plurality of semiconductor dies having first and second opposed planar surfaces; and
thermal relief means, provided between the first planar surface of a first semiconductor die of the plurality of semiconductor dies and the second planar surface of a second semiconductor die of the plurality of semiconductor dies, for conducting heat away from at least the first and second semiconductor dies and out of the semiconductor device.
